(19) United States
(12) Patent Application Publication
(10) Pub. No.: US 2007/0029653 A1
(43) Pub. Date: Feb. 8, 2007

(54) Application of autonomic self healing composites to integrated circuit packaging

(76) Inventors: Stephen E. Lehman JR., Chandler, AZ (US); Nirupama Chakrapani, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/199,682

(22) Filed: Aug. 8, 2005

(51) Int. Cl. H01L 23/02

(52) U.S. Cl. 257/678

(57) ABSTRACT

A method, apparatus and system with an autonomic, self-healing polymer capable of slowing crack propagation within the polymer and slowing delamination at a material interface.

### TECHNICAL FIELD

The invention relates to the field of microelectronics and more particularly, but not exclusively, to the application of autonomic self healing composites to integrated circuit packaging.

### BACKGROUND

The evolution of integrated circuit designs has resulted in higher operating frequency, increased numbers of transistors, and physically smaller devices. This continuing trend has generated ever increasing area densities of integrated circuits and electrical connections. To date, this trend has resulted in both increasing power and increasing heat flux devices, and the trend is expected to continue into the foreseeable future. Further, materials used in electronic packaging typically have various coefficients of thermal expansion. Under temperature fluctuations, the various coefficients of thermal expansion may lead to mechanical failures such as cracking and delamination. Still further, mechanical failures may be induced by many other causes, e.g. exposure to shock and vibration during shipping to a system or motherboard integrator, system or motherboard assembly, or shock and vibration during delivery to the end customer.

Often, solder bumps electrically and mechanically couple an integrated circuit die to a package substrate. Further, the package substrate may be electrically and mechanically coupled to a printed circuit board by solder balls. The package substrate may have a coefficient of thermal expansion different from the die and/or the printed circuit board. Under a change in temperature, a mechanical stress may result within the solder balls and solder bumps due to various coefficients of thermal expansion. In some circumstances, the solder balls and solder bumps crack under the thermally induced stress. Once a crack initiates, the crack may propagate at a rate partially dependent on a characteristic dimension of the crack, e.g., diameter at the tip of the crack.

One existing method of preventing solder ball and solder bump cracking includes dispensing a curable material in the regions between the solder balls and solder bumps (“underfilling”). When an underfill is used, some of the stress otherwise taken by the solder balls and solder bumps is taken by the underfill material and thereby reduces the likelihood of solder ball or solder bump cracking. Under the present method, if a crack initiates within the underfill, the crack may propagate through the underfill and through the solder ball and solder bump. Often underfill materials may be brittle, and thus cracks propagate readily once they initiate. In another existing method, underfill materials with increased toughness may be used to slow crack propagation. Though a crack in a brittle underfill may propagate rapidly, even a crack in a tough underfill material may still propagate.

In other circumstances, adjoining layers of material within the package may delaminate due to a mechanical stress transferred through the solder balls and solder bumps. Similar to crack propagation, a region of delamination may propagate at a rate partially dependent on a characteristic dimension of the region of delamination. One well known method of partially managing delamination failures includes applying an adhesive coating to a material interface. Similar to crack propagation, delamination may more readily propagate when an interface coating is brittle than when the interface coating is tough. Likewise, while delamination propagation in a tough interface coating may be slower than in a brittle interface coating, the delamination failure may still propagate.

Material cracking and delamination may occur under circumstances other than expansion and contraction due to temperature cycling. Circumstances under which cracking and delamination failures may occur are many. They include, among others, for example, dynamic warpage of the package during use, fatigue from temperature cycling, shock and vibration arising from shipping, assembly, and handling.

### BRIEF DESCRIPTION OF THE DRAWINGS

FIG. 1 illustrates a schematic representation of an embodiment of a polymer resin material with dispersed encapsulated resin and hardener.

FIG. 2 illustrates a schematic representation of a crack propagation and arresting in an embodiment of a material with dispersed encapsulated resin and hardener.

FIG. 3 illustrates a schematic representation of an embodiment of an integrated circuit package with an interface material including dispersed encapsulated resin and hardener.

FIG. 4 illustrates a portion of an embodiment of an integrated circuit package with an interface material including dispersed encapsulated resin and hardener.

FIG. 5 illustrates a portion of an embodiment of an integrated circuit package with an interface material including dispersed encapsulated resin and hardener, a delamination crack initiating in the interface material.

FIG. 6 illustrates a portion of the FIG. 5 embodiment of an integrated circuit package with an interface material including dispersed encapsulated resin and hardener, the delamination crack of FIG. 5 arrested by rupture of the encapsulants and polymerization of the resin and hardener.

FIG. 7 illustrates an embodiment of a material with dispersed encapsulated resin and hardener applied to an underfill region, the underfill region with a crack failure arrested by rupture of the encapsulants and polymerization of the resin and hardener.

FIG. 8 illustrates a system schematic incorporating an embodiment of a package including a material with dispersed encapsulated resin and hardener.

FIG. 9 illustrates an embodiment of a method of including a separately encapsulated resin and hardener within a package containing an integrated circuit.

### DETAILED DESCRIPTION

Herein disclosed are a method for including, and an apparatus and system that includes, an autonomic, self-healing material that may arrest delamination and crack growth.

In the following detailed description, reference is made to the accompanying drawings which form a part hereof wherein like numerals designate like parts throughout, and in which is shown by way of illustration specific embodiments in which the invention may be practiced. Other embodiments may be utilized and structural or logical changes may be made without departing from the intended scope of the embodiments presented. It should also be noted that directions and references (e.g., up, down, top, bottom, primary side, backside, etc.) may be used to facilitate the discussion of the drawings and are not intended to restrict the application of the embodiments of this invention. Therefore, the following detailed description is not to be taken in a limiting sense and the scope of the embodiments of the present invention is defined by the appended claims and their equivalents.

### Self Healing Materials

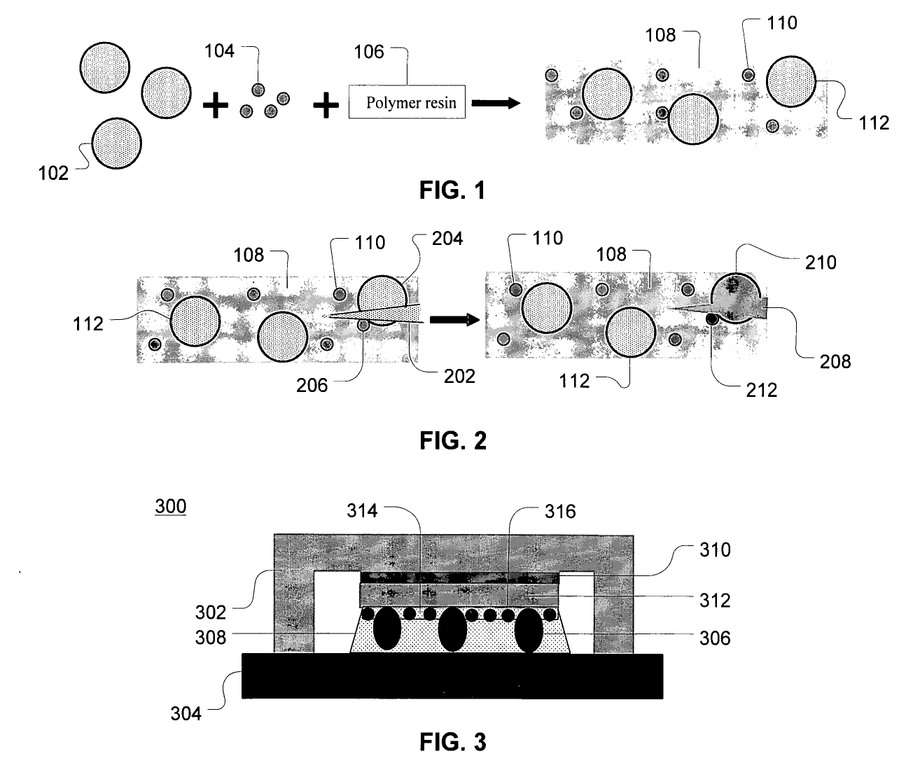

FIG. 1 illustrates an embodiment of a self healing material. A self healing material may be formed by dispersing one or more encapsulated monomers, and chain extended forms thereof, capable of hardening within an acceptable period of time (e.g., minutes, seconds, or fractions thereof) within a matrix material 106. An embodiment of the encapsulated monomers may include encapsulated resin 102 and encapsulated hardener 104.

Reference to “monomers” means monomers, and chain extended forms of monomers, capable of polymerizing upon mixing with other monomers and monomer systems.

Reference to “monomer systems” means a group of two or more monomers that may polymerize upon mixing.

As in FIG. 1, an embodiment of the matrix material 106 may be a polymer resin that cures to a solid. The resulting self healing material may include a dispersion of encapsulated monomers 112 and 110 within a solid matrix material 108. Several types of matrix material 106 and 108 may exist and the present invention may be practiced using the several types of matrix material.

Embodiments of the encapsulated resin 102 may include epoxy resins. Alternative embodiments may include isocyanate resins. Further embodiments of epoxy resins and isocyanate resins may include, among other compounds, bisphenol-A diglycidl ether, chain extended forms of bisphenol-A diglycidyl ether, bisphenol-F diglycidyl ether, chain extended forms of bisphenol-F diglycidyl ether, novolac glycidyl ether, cresol-novolac glycidyl ether, cycloaliphatic moieties, long chain aliphatic moieties, DER 354, DER 332, DER 330, DER 732, DER 736, aromatic diisocyanates, aliphatic diisocyanates, toluene diisocyanate, hydrogenated diisocyante, methylenediphenyl diisocyanate, hydrogenated methylenediphenyl diisocyanate, Desmodur N3200, Desmodur N3300, Desmodur DA, Desmodur DN, equivalents thereof, or a combination thereof.

Embodiments of the encapsulated hardener 104 may include polyols, polyamines, diamines, Ancamide 2137, Ancamide 2349, Ancamide 2353, Ancamide 2424, Ancamide 2445, Ancamide 1637, Ancamide 2089M, Demophen 550U, Multranol 9109, Baycoll ND 2060, Hardener OZ, equivalents thereof, or a combination thereof.

Still other embodiments of monomer systems may include cyanate esters, vinyl or acrylic resins with free radical initiators (e.g., peroxides), and silicone rubbers (e.g., PDMS, RTV).

FIG. 2 illustrates an embodiment of a self healing material with matrix material 108 and a dispersion of encapsulated resin 112 and encapsulated hardener 110 with a crack 202 propagating through the self healing material. As shown in FIG. 2, a crack 202 may rupture a volume of encapsulated resin 204 and a volume of encapsulated hardener 206. Further, also as shown in FIG. 2, the ruptured volume of encapsulated resin 204 may release some resin within the crack 202. Further, the ruptured volume of encapsulated hardener 206 may release some hardener within the crack. Upon mixing, the resin and hardener may cure within the crack 208, possibly changing a characteristic dimension of the crack (e.g., increasing the diameter at the tip of the crack). Because rate of crack propagation may partially depend on a characteristic dimension of the crack, crack propagation rate may slow or halt if the crack fills with several monomers that polymerize to a solid. Further, some polymerization may occur within the ruptured and partially drained encapsulated volume of resin 210 and within the ruptured and partially drained volume of hardener 212.

### Self Healing Materials to Retard Delamination

FIG. 3 illustrates one of many embodiments of a package containing an integrated circuit and at least one region of adjoining materials of different composition. An embodiment, as shown in FIG. 3, may include a package substrate 304 electrically coupled to an integrated circuit die 312 through an array of solder bumps 306. The array of solder bumps 306 may form voids subsequently filled with an underfill material (e.g., an epoxy or other polymer) 308. Further, an integrated heat spreader 302 thermally coupled to the die 312 using a thermal interface material 310 may be present in an embodiment. The embodiment of FIG. 3 also illustrates a film of self healing material 314 with dispersed, encapsulated resin 308 and dispersed, encapsulated hardener (not shown).

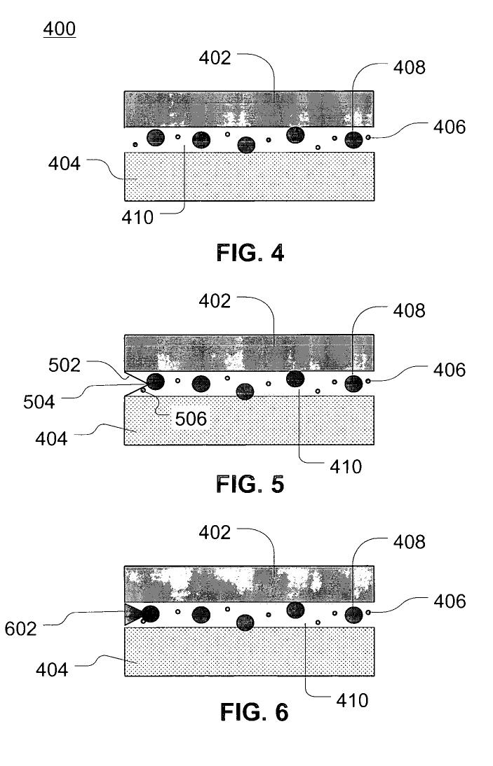

An embodiment of a self healing material applied at an interface of materials with different properties may retard delamination. Exemplary embodiments of self healing materials applied to an interface of different materials may include an interface between a die-attach and die and a mold compound to underfill. Other embodiments may exist and the partial listing of embodiments is not meant to be limiting. An embodiment of a self healing material applied at an interface between and underfill 308 and a die 312 may slow or prevent delamination cracks from damaging circuits within the package 300 by filling the cracks with monomers that polymerize prior to, or during, crack propagation. Shown in FIG. 4 is a region 400 of an embodiment of a package with die 402 and underfill 404 separated by a layer of an embodiment of self healing material 410, the self healing material 410 with a dispersion of encapsulated resin 408 and encapsulated hardener 406. In FIG. 5, a delamination crack 502 may form and begin to propagate within a self healing material 410. The crack tip 504 may rupture an encapsulated volume of resin and an encapsulated volume of hardener 506. Some resin and hardener may partially fill the crack, as in FIG. 6, and cure. The resulting crack 602 may have an altered characteristic dimension and thus may have retarded propagation.

### Self Healing Materials as Underfill

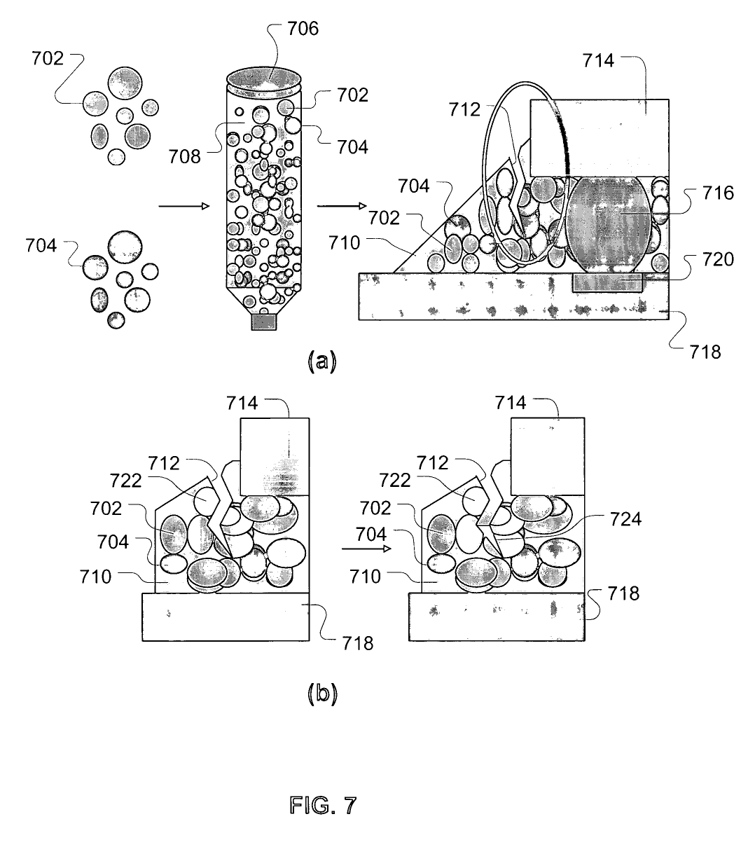

An embodiment of a self healing material may be used as underfill material. One embodiment of an underfill is a die underfill. Alternative embodiments of self healing materials used as underfill may include underfill to a substrate solder resist and underfill to a die passivation layer. Other embodiments of underfill materials may exist and the partial listing of alternatives is not meant to be limiting. FIG. 7 illustrates several articles of manufacture in one embodiment of a self healing material used as a die underfill. FIG. 7(a) illustrates a dispersion of encapsulated monomers 702 and 704 (e.g., resin and hardener) included in a matrix material 708, the resulting matrix material and dispersion filling a tool 706 for application of die underfill material 710. An embodiment of die underfill 710, as shown in FIG. 7, may fill a void between a die 714 and substrate 718, the substrate 718 and die 714 electrically coupled by a solder bump 716 and a solder pad 720. A crack 712 may form in the underfill and propagate, rupturing volumes of encapsulated monomers 702 and 704. The crack through an embodiment of a self healing material used as underfill may partially fill with a curable mixture 724 of resin and hardener and thereby retard crack propagation through the die underfill.

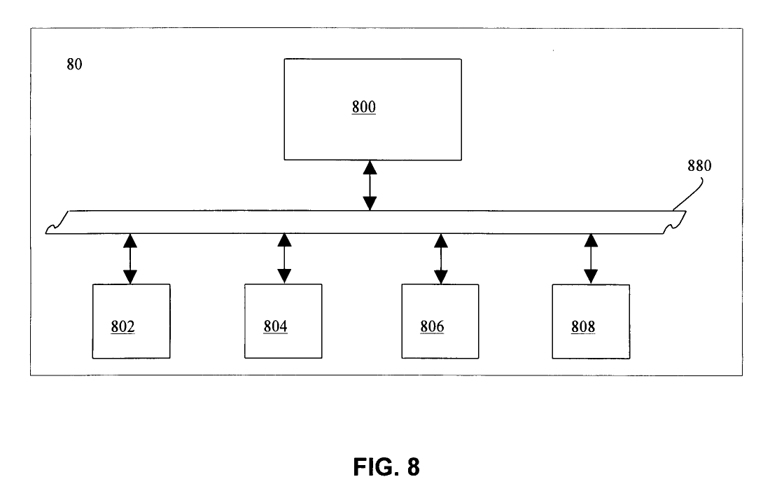

FIG. 8 illustrates a schematic representation of one of many possible system embodiments. In an embodiment, the package containing an integrated circuit 800 may include a self healing material. One embodiment may include an interface layer of self healing material similar to the layer of self healing material illustrated in FIG. 3-FIG. 6. In an alternative embodiment, the package containing an integrated circuit 800 may include a self-healing underfill material similar to the embodiment shown in FIG. 7. In another embodiment, the integrated circuit may include a microprocessor. In a further alternate embodiment, the integrated circuit package may include an application specific integrated circuit (ASIC). Integrated circuits found in chipsets (e.g., graphics, sound, and control chipsets) or memory may also be packaged in accordance with embodiments of this invention.

For an embodiment similar to the embodiment depicted in FIG. 8, the system 80 may also include a main memory 802, a graphics processor 804, a mass storage device 806, and an input/output module 808 coupled to each other by way of a bus 810, as shown. Examples of the memory 802 include but are not limited to static random access memory (SRAM) and dynamic random access memory (DRAM). Examples of the mass storage device 806 include but are not limited to a hard disk drive, a flash drive, a compact disk drive (CD), a digital versatile disk drive (DVD), and so forth. Examples of the input/output modules 808 include but are not limited to a keyboard, cursor control devices, a display, a network interface, and so forth. Examples of the bus 810 include but are not limited to a peripheral control interface (PCI) bus, PCI Express bus, Industry Standard Architecture (ISA) bus, and so forth. In various embodiments, the system 80 may be a wireless mobile phone, a personal digital assistant, a pocket PC, a tablet PC, a notebook PC, a desktop computer, a set-top box, an audio/video controller, a DVD player, a network router, a network switching device, or a server.

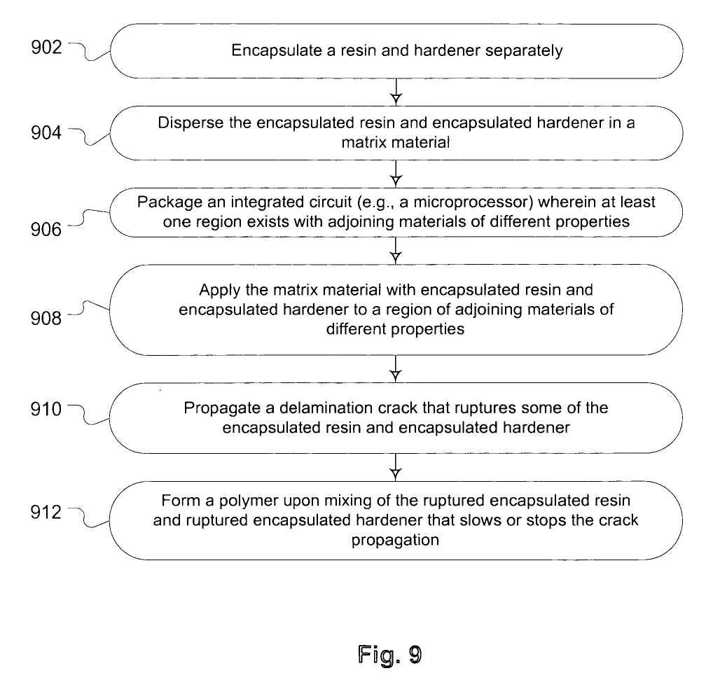

FIG. 9 illustrates one embodiment of a method of self healing a crack in a package material. A resin and hardener may be encapsulated separately 902 and dispersed in a matrix material 904. An integrated circuit may be packaged such that one region exists with adjoining materials, the materials having different material properties 906. The matrix material with independently encapsulated resin and hardener may be applied to the region of adjoining materials of different properties 908. A delamination crack may propagate and rupture some of the encapsulated volumes of resin and hardener 910 and polymerize upon mixing and further retard propagation of the delamination crack 912.

Although specific embodiments have been illustrated and described herein for purposes of description of an embodiment, it will be appreciated by those of ordinary skill in the art that a wide variety of alternate and/or equivalent implementations calculated to achieve similar purposes may be substituted for the specific embodiments shown and described without departing from the scope of the present disclosure. For example, an alternative embodiment may exist where a layer of self healing material may be used between a die and integrated heat spreader. Another embodiment may apply a self healing underfill material between a package substrate and printed circuit board. Yet another embodiment may exist wherein a self healing material forms an underfill of solder balls on a chip scale package. Further, encapsulated monomers may be dispersed through out a material forming part of an underfill, a mold compound, a die-attach, or a stress compensation layer.

Those with skill in the art will readily appreciate that the present invention may be implemented using a very wide variety of embodiments. This detailed description is intended to cover any adaptations or variations of the embodiments discussed herein. Therefore, it is manifestly intended that this invention be limited only by the claims and the equivalents thereof.

1. An apparatus comprising:
a package including an integrated circuit, the package further including one or more regions of adjacent materials of different composition;
a film disposed between the materials of different composition at one or more of the regions, wherein the film includes an encapsulated monomer system dispersed substantially throughout the film and wherein the monomers of the monomer system are encapsulated separately from other monomers of the monomer system.

2. The apparatus of claim 1, the integrated circuit further comprising a microprocessor.

3. The apparatus of claim 1, wherein the region of adjacent materials of different composition is selected from the group consisting of a region of die underfill and die, a region of die and thermal interface material, a region of die and integrated heat spreader, a region of die and package substrate, a region of package substrate and solder balls, and a combination thereof.

4. The apparatus of claim 1, wherein the encapsulated monomer system polymerizes upon mixing.

5. The apparatus of claim 1, wherein one of the regions of adjacent materials of different composition includes a delamination crack partially filled with a polymer.

6. The apparatus of claim 5, wherein the polymer results from polymerization of the encapsulated monomer system, the encapsulated monomer system ruptured by the delamination crack.

7. The apparatus of claim 1, wherein the encapsulated monomer system able to polymerize further comprises one selected from the group including a resin, a hardener, a cyanate ester, a vinyl resin, an acrylic resin, a free radical initiator, and a two part silicone rubber, and combinations thereof.

8. The apparatus of claim 1, the monomer system further comprising a resin selected from the group consisting of bisphenol-A diglycidyl ether, chain extended forms of bisphenol-A diglycidyl ether, bisphenol-F diglycidyl ether, chain extended forms of bisphenol-F diglycidyl ether, novolac glycidyl ether, cresol-novolac glycidyl ether, cycloaliphatic moieties, long chain aliphatic moieties, aromatic diisocyanates, aliphatic diisocyanates, toluene diisocyanate, hydrogenated diisocyanate, methylenediphenyl diisocyanate, hydrogenated methylenediphenyl diisocyanate, Desmodur N3200, Desmodur N3300, Desmodur DA, Desmodur DN, and a combination thereof.

9. The apparatus of claim 1, the monomer system further comprising a hardener selected from the group consisting of polyols, polyamines, diamines, and a combination thereof.

10. A method comprising:
encapsulating a monomer system, the monomers of the monomer system encapsulated separately from other monomers of the monomer system;
dispersing the encapsulated monomer system in a matrix material; and,
including the matrix material with dispersed encapsulated monomer system as a film disposed between two or more adjacent materials of different composition within a package including an integrated circuit.

11. The method of claim 10, wherein the integrated circuit comprises a microprocessor.

12. The method of claim 10, the monomer system further comprising a resin selected from the group consisting of bisphenol-A diglycidyl ether, chain extended forms of bisphenol-A diglycidyl ether, bisphenol-F diglycidyl ether, chain extended forms of bisphenol-F diglycidyl ether, novolac glycidyl ether, cresol-novolac glycidyl ether, cycloaliphatic moieties, long chain aliphatic moieties, aromatic diisocyanates, aliphatic diisocyanates, toluene diisocyanate, hydrogenated diisocyanate, methylenediphenyl diisocyanate, hydrogenated methylenediphenyl diisocyanate, Desmodur N3200, Desmodur N3300, Desmodur DA, Desmodur DN, and a combination thereof.

13. The method of claim 10, the monomer system further comprising a hardener selected from the group consisting of polyols, polyamines, diamines, and a combination thereof

14. The method of claim 10, wherein the film includes a delamination crack partially filled with a polymer.

15. The method of claim 14, wherein the polymer results from polymerization of the microencapsulated resin and hardener, the microencapsulated resin and hardener ruptured by the delamination crack.

16. A system comprising:
a package including an integrated circuit, the package including one or more regions of adjacent materials of different composition;
a film disposed between the materials of different composition at one or more of the regions, wherein the film includes an encapsulated monomer system dispersed substantially throughout, and wherein the monomers of the monomer system are encapsulated separately from other monomers of the monomer system, and
a mass storage device coupled to the package.

17. The system of claim 16, further comprising:
a dynamic random access memory coupled to the integrated circuit; and
an input/output interface coupled to the integrated circuit.

18. The system of claim 17, wherein the input/output interface comprises a networking interface.

19. The system of claim 16, wherein the integrated circuit is a processor.

20. The system of claim 19, wherein the system is a selected one of a group comprising a set-top box, a media-center personal computer, a digital versatile disk player, a server, a personal computer, a mobile personal computer, a network router, and a network switching device.

21. The system of claim 16, wherein a polymer partially fills a delamination crack in the package, wherein the polymer formed by polymerization of the encapsulated monomer system released by the delamination crack.
